(19) United States
(12) Patent Application Publication
(10) Pub. No.: US 2004/0237757 A1
(43) Pub. Date: Dec. 2, 2004

(54) System and method for representing playing of musical instruments

(76) Inventor: Robert E. Alling, Scottsdale, AZ (US)

Correspondence Address: GREENBERG TRAURIG LLP, 2450 COLORADO AVENUE, SUITE 400E, SANTA MONICA, CA, 90404, US

(21) Appl. No.: 10/805,003

(22) Filed: Mar. 18, 2004

Related U.S. Application Data
(60) Provisional application No. 60/456,010, filed on Mar. 19, 2003.

(51) Int. Cl. H03M 1/00; G11C 5/00; G10H 1/32; G10H 7/00; G10H 5/00

(52) U.S. Cl. 84/601

(57) ABSTRACT

Live musical performances are archived for presentation on multimedia. Multiple cameras record multiple views of the performance and multiple audio tracks are professionally mixed for audio clarity. The recording on the media of music information from the performance includes one of video, audio, and textual content from a musical instrument played by a performer. The display to the viewer of the music information on the media is through a plurality of windows. One window depicts a detailed view of the musical instrument being played by the performer. The media are a CD, DVD, or any other media capable of recording audio, video, and text. The textual information could be music notes, performer's name, the place and date of performance, composer and composition information.

### RELATED APPLICATION

This application claims priority to U.S. Provisional Application Ser. No. 60/456,010, filed Mar. 19, 2003 entitled “System and Method for Representing Playing of Musical Instruments”, the contents of which are incorporated by reference herein in their entirety.

### BACKGROUND

The present disclosure relates to recording, delivering, and presenting high quality multimedia (audio, video, text) for archiving and instructional purposes via DVD, CD, Internet or other media.

### SUMMARY

The system disclosed is used for archiving live piano performances or other instruments on CD, DVD or other media.

There is a need for a standard format for the archiving of piano artists' live performance. Currently artists record the audio portion of their performance for instruction, broadcast or CD production. Every performance of a musical work is individual to the performer and the work being played.

An integral part of that performance is the artist's physical actions during the performance. If not recorded, the performance is lost for the future. In addition, the ability to study a performer as their career progresses is available only to the few who are able to attend an artist's multiple performances over time. The present disclosure provides the artist and the audience with a long-term archive of performances over an artist's lifetime.

This disclosure provides a system and a method for archiving and presenting musical information (viz., the musical performance) for: (i) music appreciation, and (ii) enabling effective feedback to improve music performance skills.

Accordingly, in one embodiment the method for presenting music information to a viewer from a media comprises recording on the media, through audio and video means, the music information relating to the performance, wherein the music information includes content from a musical instrument (e.g., piano, guitar, drums, etc.) played by a performer. There is presented to the viewer the music information, through multiple windows. At least one window depicts a detailed view of the musical instrument being played by the performer.

Furthermore, the system for providing music information to a viewer from a media comprises a means for recording, on the media, music information from the music performance, wherein the music information includes at least one of video, audio, and textual content from a musical instrument played by a performer. There is a display for presenting to the viewer the music information on the media, through a plurality of windows. At least one window depicts a detailed view of the musical instrument being played by the performer.

A method is provided of recording an artist's performance, to capture both the audio and video record. Live performance is as much the sound coming from the instrument, as the passion the artist displays in playing the music. For a truly complete experience, the audience needs to see the artist's hands, posture and face to truly understand performance.

Multiple cameras are used to record the overhead view of the performer's hands and arms, a view from the audience and a view of the performer's face during the performance.

The performance audio is professionally mixed for optimum audio clarity. With the recording of both the audio and visual portions of the performance, there is a permanent record of an artist's interpretation and performance of an individual work.

After the performance, the three video views and the audio track are digitized. Using software applications such as Final Cut Pro™, Photoshop™, Adobe After Effects™ etc., the multiple artist views and audio are synced, composited and downloaded to a DVD or other media.

The final product is a composite of multiple views of the performer and the audio from the performance. The product can play one or multiple views of the pianist's performance. There is also the opportunity to provide artist commentary on the performance, work played, or the artist themselves.

Program Notes provided by the artist, critics or scholars on the piece and performance may also be included on the product.

The disclosure is further described with reference to the accompanying drawings.

### DRAWINGS

FIG. 1 is an exemplary depiction of presenting a musical performance using multiple windows.

FIG. 2 is an exemplary depiction of a system of cameras and controllers for capturing different views of an instrument/performer at a live musical performance.

FIG. 3 is a depiction of the stage layout and the positions of the cameras in relation to the piano/performer.

### DESCRIPTION

In an exemplary depiction, if the instrument is a piano, the detailed view of the piano is obtained by a camera positioned substantially above the piano key-set, thereby clearly showing the fingers of the performer moving over the piano key-set while performing.

Furthermore, additional windows are used to present different views of the instrument and/or the performer performing with the instrument. These additional views are obtained through additional cameras being strategically positioned in relation to the performer/instrument. For example, the cameras are positioned in a manner to present substantially orthogonal views of the instrument/performer in the windows. In an exemplary depiction, the different viewpoints include a top-down view of the instrument, side view of the performer performing with the instrument, and a front view of the performer performing with the instrument.

In one aspect, the media are at least one of a CD, DVD, or any other media capable of recording audio, video, and text. The textual information includes music notes, name of the performer, the place of performance, the date of performance, composer information, and composition information. The media is authored so that the performance, including the various windows displaying the performer/instrument/text, and recorded by techniques well known in the art.

Presenting such detailed information/views to a viewer: (i) enables the viewer to appreciate the performance, and (ii) provides an educational tool to the viewer for understanding the art of performing with the instrument.

Real-time or downloadable music content related to the musical performance is delivered through the Internet and presented to the viewer in a multiple window format. In this format, at least one window depicts a detailed view of the musical instrument being played by the performer.

In another embodiment, music content related to the musical performance is delivered through a standard TV broadcasting system, cable television, or a wireless medium (e.g., in cellular phone environment). The music content (audio, video, and text) is presented to the viewer in a multiple window format, wherein each window may provide a unique view of the instrument to enable the viewer to appreciate the performance, or perfect the art of performing with the instrument.

In an alternative embodiment, music content related to the musical performance is presented live, on a video projector screen, along with the musical performance in an auditorium/concert hall. Specifically, the music content (video and text) is presented to the viewer in a multiple window format, wherein each window provides a unique view of the instrument/performer.

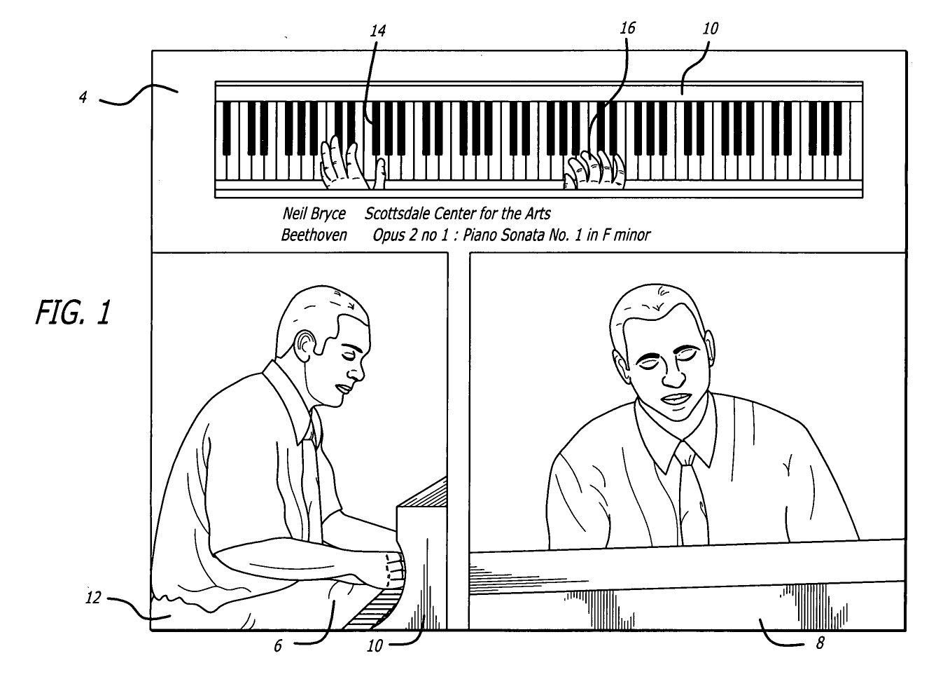

In an exemplary depiction, FIG. 1 shows three windows 4, 6, and 8, wherein each window has a different view of the musical instrument 10 and the performer 12 playing the instrument 10. The three views may be obtained via three different cameras positioned strategically around the instrument/performer so that each of the displayed windows may provide a unique view of the instrument/performer. This enables the viewer to appreciate the performance, or perfect the art of performing with the instrument.

Specifically, the top-down view in window 4 is a detailed view of the instrument (viz., the piano) and may capture the movement of the performer's fingers 16 along the key-set 14 of the piano 10. This view allows the viewer to watch and understand the performer's playing style in substantial detail. In addition, the views in windows 6 and 8 are orthogonal to each other and to the view in window 4, and permit the viewer to watch the emotions and general mannerisms of the performer 12 while playing the instrument 10.

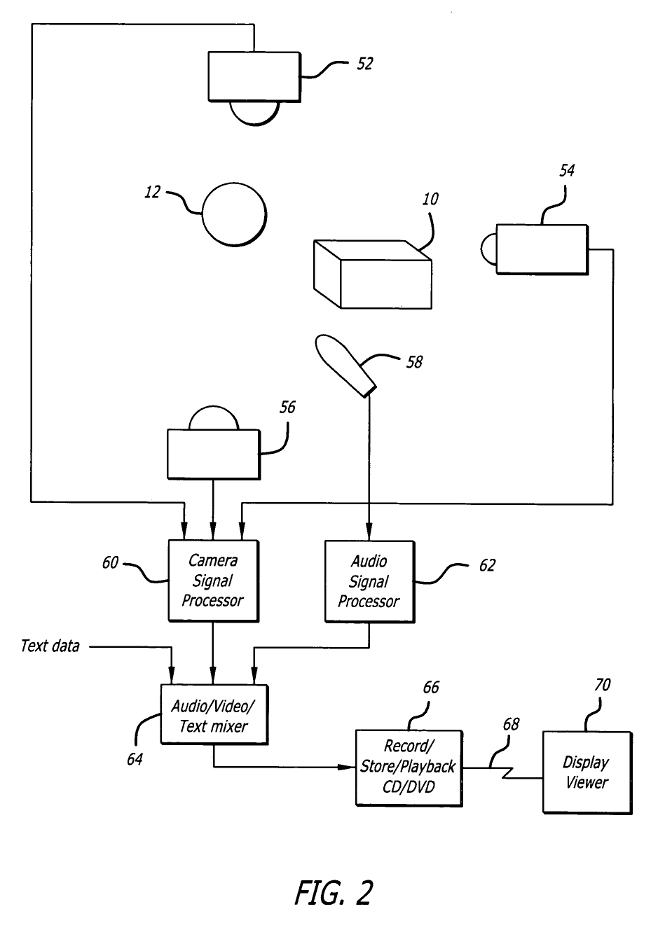

In an exemplary depiction, FIG. 2 shows the system for recording/playback of audio, video, and text information. Specifically, the three cameras 52, 54, and 56 capture the three orthogonal views (top-down, front, and side) of the instrument/performer, while the microphone 58 records the audio portion. The video and audio information is delivered to the camera signal processor 60 and audio signal processor 62 for post-processing. The output from the processors is combined, with the information from a text generator, at a mixer 64, and subsequently delivered for live playback or for storage 66. From the storage 66 the material can be sent through the Internet 68 to another viewer or display 70.

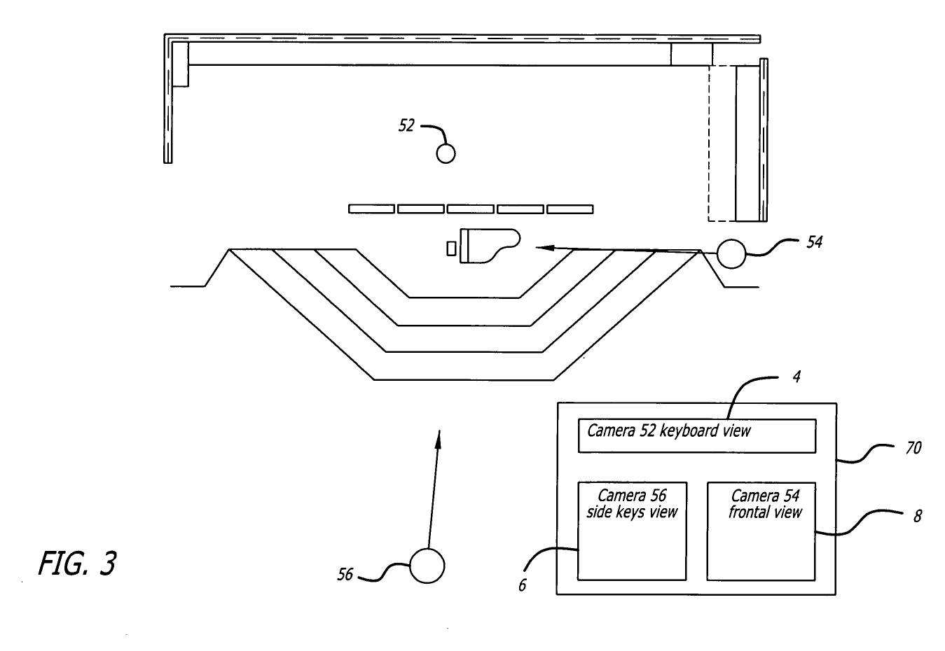

FIG. 3 shows a general layout of the cameras in relation to the audience, the performer, and the musical instrument. It should be noted that the camera positions can be different, and additional cameras can be used to capture, and subsequently present, detailed information pertaining to the performance.

In summary, presenting such detailed information/views about the musical performance to a viewer: (i) enables the viewer to appreciate the performance, and (ii) provides an educational tool to the viewer for understanding the art of performing with the instrument.

Currently artists, music festivals and competitions often record the audio portion of a performance for archives, broadcast on PBS stations or CD sales. The present disclosure provides a more comprehensive form of archive of a performance. Individual artists have the opportunity to have an archive of a lifetime of work and additional material for commercial recordings.

Festivals and competitions may choose to use the present disclosure to provide a performance experience to patrons who cannot attend the live performance. Artists and educators are able to use the disclosure as a teaching tool. Educators are able to compare different artists performing the same work. Artists are able to critique their live performance such as athletes use playback tapes of games. Furthermore, the present disclosure is a comprehensive archival method for live piano performance for use by artists, festivals, competitions and others.

Descriptions of exemplary embodiments of the disclosure are provided. It is to be understood that other embodiments may be utilized and structural and functional changes may be made without departing from the respective scope of the present disclosure.

The exemplary embodiments of the disclosure have been presented for the purposes of illustration and description. They are not intended to be exhaustive or to limit the disclosure to the precise forms disclosed. Many modifications and variations are possible in light of the teachings herein. For instance, instead of a piano, other keyboard instruments or different kinds of instruments can be the subject of the disclosure.

The scope of the disclosure is to be determined solely by the following claims.

We claim:

1. A method for presenting music information to a viewer from a media, the method comprising:
recording on the media, through audio and video means, the music information relating to the performance, wherein the music information includes content from a musical instrument played by a performer; and
presenting to the viewer the music information on the media, through a plurality of windows, wherein at least one window depicts a view of the musical instrument being played by the performer.

2. The method according to claim 1, wherein the media are at least one of a CD, DVD or other media capable of recording musical information.

3. The method according to claim 1, wherein at least one window is used for presenting textual information.

4. The method according to claim 3, wherein the textual information includes music notes.

5. The method according to claim 3, wherein the textual information includes at least one of a name of the performer, the place of performance, the date of performance, composer information, and composition information.

6. The method according to claim 1, wherein at least one window is used for providing visual feedback of the performer playing the musical instrument.

7. The method according to claim 1, wherein the musical instrument is a piano or other instrument.

8. The method according to claim 7, wherein the view of the instrument is obtained by a camera positioned substantially above the instrument.

9. A method for delivering music information to a viewer via the Internet, the method comprising:
recording a live performance, through audio and video means, the music information related to the performance, wherein the music information includes content from a musical instrument played by a performer;
delivering the music information in real-time through the Internet to the viewer; and
presenting to the viewer the music information, through a plurality of windows, wherein at least one window depicts a view of the musical instrument being played by the performer.

10. The method according to claim 9, wherein at least one window is used for presenting textual information.

11. The method according to claim 10, wherein the textual information includes music notes.

12. The method according to claim 10, wherein the textual information includes at least one of a name of the performer, the place of performance, the date of performance, composer information, and composition information.

13. The method according to claim 9, wherein at least one window is used for providing visual feedback of the performer playing the musical instrument.

14. The method according to claim 9, wherein the musical instrument is a piano or other instrument.

15. The method according to claim 14, wherein the detailed view of the instrument is obtained by a camera positioned above the instrument.

16. A system for providing music information to a viewer from a media, the system comprising:
a recorder for recording, on the media, music information from the music performance, wherein the music information includes at least one of video, audio, and textual content from a musical instrument played by a performer; and
a display for presenting to the viewer the music information on the media, through a plurality of windows, wherein at least one window depicts a detailed view of the musical instrument being played by the performer.
